(19) United States
(12) Patent Application Publication
(10) Pub. No.: US 2007/0087541 A1
(43) Pub. Date: Apr. 19, 2007

(54) METHOD AND APPARATUS FOR DEPOSITION & FORMATION OF METAL SILICIDES

(76) Inventors: Kenneth John Giewont, Hopewell Junction, NY (US); Bradley Paul Jones, Pleasant Valley, NY (US); Christian Lavoie, Ossining, NY (US); Robert J. Purtell, Mohegan Lake, NY (US); Yun-Yu Wang, Poughquag, NY (US); Kwong Hon Wong, Wappingers Falls, NY (US)

Correspondence Address: Frederick W. Gibb, III;McGinn & Gibb, PLLC, Suite 304, 2568-A Riva Road, Annapolis, MD, 21401, US

(21) Appl. No.: 11/557,259

(22) Filed: Nov. 7, 2006

Related U.S. Application Data
(62) Division of application No. 10/674,302, filed on Sep. 30, 2003.

(51) Int. Cl. H01L 21/4763; H01L 21/3205

(52) U.S. Cl. 438/592

(57) ABSTRACT

Disclosed is a method and structure for forming a silicide on a silicon material. The invention places the silicon material in a vacuum environment, forms metal on the silicon material, and then heats the silicon surface and the metal without breaking the vacuum environment. The processes of forming the metal and heating the silicon can be performed simultaneously without breaking the vacuum environment to form the silicide as the metal is being deposited. After the foregoing processing, the invention can remove the silicon surface from the vacuum environment and perform additional heating of the silicon surface. The first heating process forms a monosilicide and the additional heating forms a disilicide.

### CROSS-REFERENCE TO RELATED APPLICATIONS

This application is a division of U.S. application Ser. No. 10/674,302 filed Sep. 30, 2003.

### BACKGROUND OF THE INVENTION

1. Field of the Invention

The present invention generally relates to silicide formation and more particularly to an improved method and system that deposit metal and heats the silicon and metal without breaking vacuum.

2. Description of the Related Art

A silicide is often formed on silicon surfaces to decrease resistivity of the silicon. More specifically, a metal is deposited on the silicon surface and the structure is heated. This produces a silicide on the silicon surface. Conventional systems first form the metal and then move the structure to a heating tool to perform the heating process. However, this allows ambient materials, such as oxygen, to have a detrimental effect upon the metal that is used in the silicide process. Therefore, conventional systems often form a protective layer over the silicide metal. This protective layer must eventually be removed.

The invention described below eliminates the need for this protective layer (and its removal) by forming the metal and heating the structure without breaking vacuum. Therefore, with the invention described below, oxygen and other ambients are prevented from affecting the metal used in the silicide process.

### SUMMARY OF THE INVENTION

The invention provides methods and structures for forming a silicide on a silicon material. The invention places the silicon material in a vacuum environment, forms metal on the silicon material, and then heats the silicon surface and the metal without breaking the vacuum environment. The processes of forming the metal and heating the silicon can be performed simultaneously without breaking the vacuum environment to form the silicide as the metal is being deposited. After the foregoing processing, the invention can remove the silicon surface from the vacuum environment and perform additional heating of the silicon surface. The first heating process forms a monosilicide and the additional heating forms a disilicide. More specifically, the first heating process is performed at temperatures between 300° C. and 400° C. to form a metal rich silicide or between temperatures of 450° C. and 550° C. to form a monosilicide, and the additional heating is performed at temperatures above 600° C. to form a disilicide. The metal can comprise Cobalt, Nickel, etc.

To perform the foregoing processing, the invention provides a system that includes a vacuum chamber adapted to hold the silicon material under a vacuum environment. A metal formation tool is connected to the vacuum chamber and is adapted to form metal on the silicon material while the silicon material is under the vacuum environment within the vacuum chamber. Additionally, a heating tool is connected to the vacuum chamber and adapted to heat the silicon while the silicon material is under the vacuum environment within the vacuum chamber.

In one embodiment, the heating tool heats the silicon simultaneously while the metal formation tool deposits the metal on the silicon material, so that a silicide material is formed as the metal is deposited on the silicon material. In this embodiment, the heating tool comprises a heated chuck having, for example, a resistive heater.

The system can also include an etch tool (e.g., wet etch, etc.) external to the vacuum chamber that performs wet etching of the unreacted metal after the silicon material is removed from the vacuum chamber. The system can further include a second heating tool (possibly external to the vacuum chamber) that is adapted to heat the silicon material after the silicon material is removed from the vacuum chamber and after it undergoes the etching process. This second heating tool is adapted to heat the silicon material to temperatures above 600° C. to form a disilicide.

The vacuum chamber can comprise a plurality of connected vacuum chambers adapted to maintain the silicon material in a continuous vacuum environment while the metal formation tool forms the metal and while the heating tool heats the silicon material. Thus, for example, the vacuum chambers can comprise a first vacuum chamber to which the metal formation tool is attached, a second vacuum chamber to which the heating tool is attached, and a third vacuum chamber adapted to maintain the vacuum environment while transporting the silicon material from the first vacuum tool to the second vacuum tool.

These, and other, aspects and objects of the present invention will be better appreciated and understood when considered in conjunction with the following description and the accompanying drawings. It should be understood, however, that the following description, while indicating preferred embodiments of the present invention and numerous specific details thereof, is given by way of illustration and not of limitation. Many changes and modifications may be made within the scope of the present invention without departing from the spirit thereof, and the invention includes all such modifications.

### BRIEF DESCRIPTION OF THE DRAWINGS

The invention will be better understood from the following detailed description with reference to the drawings, in which:

FIG. 1 is a flow diagram illustrating a preferred method of the invention;

FIG. 2 is a schematic diagram of a system according to the invention;

FIG. 3 is a flow diagram illustrating a preferred method of the invention; and

FIG. 4 is a schematic diagram of a system according to the invention.

### DETAILED DESCRIPTION OF PREFERRED EMBODIMENTS OF THE INVENTION

The present invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the present invention in detail.

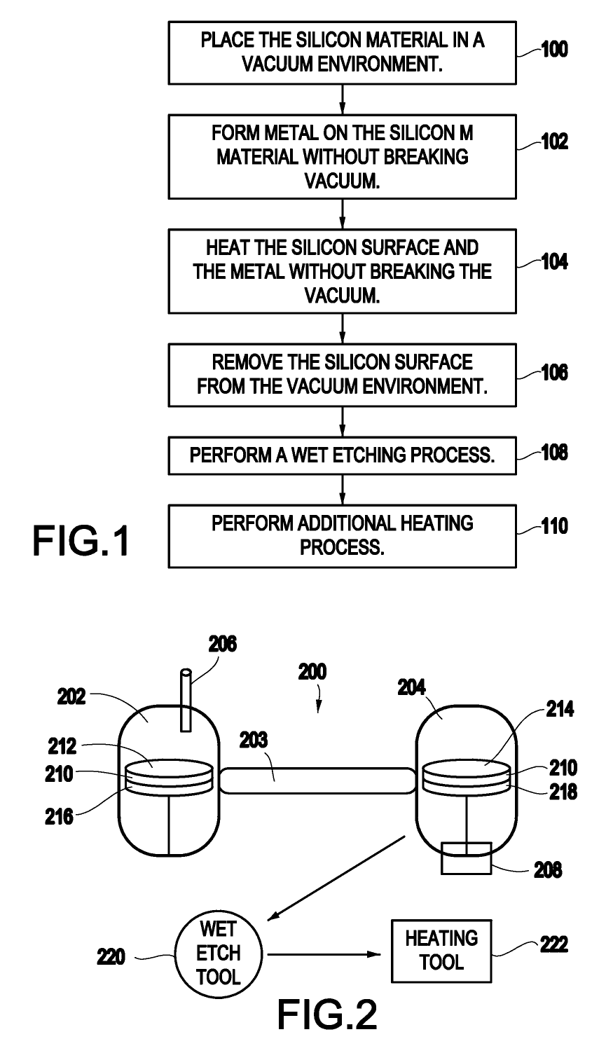

As shown in the flowchart in FIG. 1, the invention provides a method for forming a silicide on a silicon material. More specifically, in item 100, the invention places the silicon material in a vacuum environment. Then, in item 102, the invention forms (e.g., deposits) metal on the silicon material without breaking vacuum. Next, in item 104, the invention heats the silicon surface and the metal without breaking the vacuum environment.

After the foregoing processing, the invention removes the silicon surface from the vacuum environment (106) and performs a an etching process 108 (e.g., wet etching, etc.) to clean off unreacted metal and an additional heating process 110. The first heating process 104 forms a monosilicide or metal rich silicide and the additional heating forms a disilicide. More specifically, the first heating process is performed at temperatures between 300° C. and 400° C. to form a metal rich silicide or between temperatures of 450° C. and 550° C. to form a monosilicide, and the additional heating 110 is performed at temperatures above 600° C. to form a disilicide. The metal can comprise Cobalt, Nickel, etc.

The inventive system shown in FIG. 2 includes a vacuum chamber system 200 adapted to hold the silicon material 210 under a vacuum environment, using, for example chucks 216, 218. The vacuum chamber system 200 can include a plurality of connected vacuum chambers 202-204 adapted to maintain the silicon material 210 in a continuous vacuum environment while the metal formation tool forms the metal 212 and while the heating tool heats the silicon material 210 and the metal 212 to form a silicide 214. The vacuum system 200 is operated under a vacuum or with an inert gas, so the substrate is not exposed to harmful ambients (e.g., air or O₂).

Thus, for example, the vacuum chambers can comprise a first vacuum chamber 202 containing the metal formation tool 206, a second vacuum chamber 204 containing the heating tool 208, and a third vacuum chamber 203 adapted to maintain the vacuum environment while transporting the silicon material 210 from the first vacuum tool to the second vacuum tool. This vacuum chamber system 200 is merely exemplary and one ordinarily skilled in the art would understand that any number of different vacuum system could be used to maintain the silicon material 210 in a continuous vacuum environment while the metal formation tool forms the metal 212 and while the heating tool heats the silicon material 210.

Item 206 is an exemplary metal formation tool that is connected to (within) the vacuum chamber 202 and that is adapted to form metal 212 on the silicon material 210 while the silicon material 210 is under the vacuum environment within the vacuum chamber system 200. Item 208 illustrates the heating tool that is within the vacuum chamber 204 and that is adapted to heat the silicon while the silicon material 210 is under the vacuum environment within the vacuum chamber system 200.

The inventive system also includes an etch tool 220 external to the vacuum chamber system 200 that performs (wet) etching 108 of the unreacted metal 214 after the silicon material 210 is removed from the vacuum chamber system 200 (after vacuum is broken). A second heating tool 222, which can be internal or external to the vacuum chamber system 200, is adapted to heat the silicon material 210 after the etching process 108. This second heating tool is adapted to heat the silicon material to temperatures above 600° C. to form a disilicide.

Thus, the present invention forms, for example, Cobalt, Nickel, etc. silicide on a silicon substrate. In item 102, the invention deposits the metal 212 on the silicon in a vacuum process chamber 200 at a low temperature (<300° C.). The metal 212 can be, for example, Co, Ni, or other. The metal 212 can be deposited as pure metal or a metal containing a small amount (e.g., 20%) of Si, or the metal may have an overlying or underlying layer of another metal (e.g., Ti, W, TiW) or metal nitride (e.g., TiN).

As shown above, the invention anneals the metal 104 to form a metal silicide 214. The annealing chamber 202 is within the same vacuum system 200 as the metal deposition chamber(s) 204, so the wafer 210 is not exposed to the air between the metal deposition 104 and anneal 106. The anneal 106 may be at a low temperature (300-450° C.) that forms metal rich silicide (e.g., Co₂Si) or medium temperature (450-550° C.) that forms monosilicide (CoSi). This process may be supplemented by the conventional known process of removing unreacted metal (and cap/underlayer, if used) from non-reactive portions (e.g., oxide) of a patterned substrate during the wet etching 108. The second annealing 110 is performed at a high temperature (>600° C.) to form disilicide (e.g., CoSi₂).

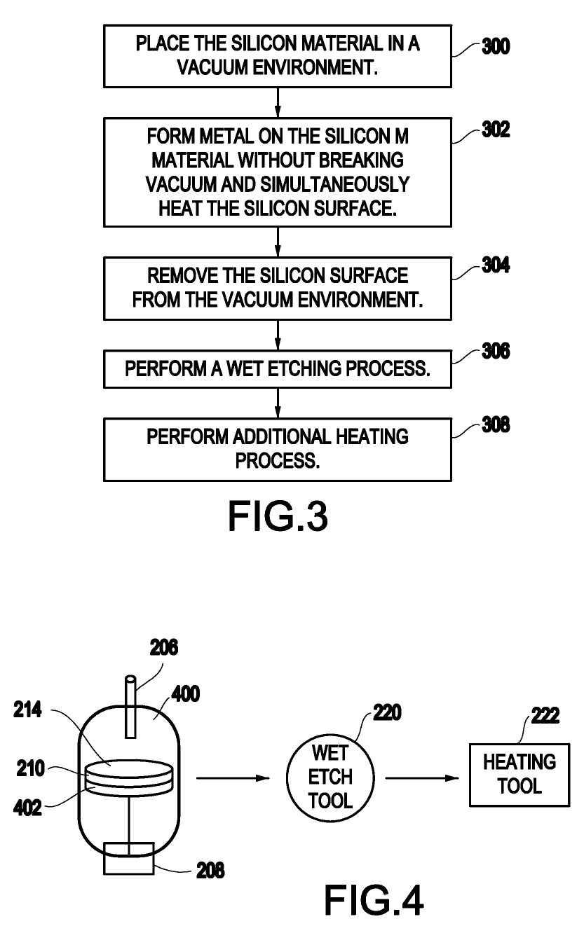

In another embodiment, shown in the flowchart in FIG. 3, the processes of forming the metal and heating the silicon are performed simultaneously without breaking the vacuum environment to form the silicide as the metal is being deposited. More specifically, in item 300, the invention places the silicon material in a vacuum environment. Then, in item 302, the invention forms (e.g., deposits) metal on the silicon material without breaking vacuum and simultaneously heats the silicon surface 210 and the metal 212 without breaking the vacuum environment. The metal deposition and heating processes 302 are substantially similar to those discussed above 102, 104 and reference is made to that previous discussion for the details of this step. After the foregoing processing, the invention again removes the silicon surface from the vacuum environment (304) and performs a wet etching process 306 and an additional heating process 308.

Thus, in this embodiment, the heating tool heats the silicon simultaneously while the metal formation tool deposits the metal 212 on the silicon material 210, so that a silicide 214 material is formed as the metal 212 is deposited on the silicon material 210. As shown in FIG. 4, in this embodiment, the heating tool can comprise a heated chuck 402 having, for example, a resistive heater, within a vacuum chamber 400. Alternatively, any other heating system 208 could be used with the vacuum chamber 400 to perform the simultaneous heating and metal deposition.

As shown above, the invention provides a method and system that deposits metal and heats silicon in a vacuum to avoid having oxygen and other harmful ambients present when siliciding. This eliminates the need to form protective barriers, thereby eliminating many processing steps. This reduces costs, decreases manufacturing processing time, and also increases yield as removing processes decreases the chance that a defective process may occur.

While the invention has been described in terms of preferred embodiments, those skilled in the art will recognize that the invention can be practiced with modification within the spirit and scope of the appended claims.

What is claimed is:

1. A method of forming a silicide on a silicon material comprising:
placing said silicon material in vacuum environment;
forming metal on said silicon material without breaking said vacuum environment; and
heating said silicon material and said metal during said forming of said metal without breaking said vacuum environment.

2. The method in claim 1, further comprising performing additional heating of said silicon material.

3. The method in claim 2, wherein said heating forms a monosilicide and said additional heating forms a disilicide.

4. The method in claim 2, wherein said heating is performed at temperatures between 300° C. and 400° C. to form a metal rich silicide or between temperatures of 450° C. and 550° C. to form a monosilicide, and said additional heating is performed at temperatures above 600° C. to form a disilicide.

5. The method in claim 1, wherein said metal comprises one of Cobalt, Titanium, Platinum, and Nickel.

6. The method of claim 1, wherein said heating of said silicon material and of said metal comprises heating said silicon material and said metal such that said silicon material and said metal are heated on a heating chuck holding said silicon material.

7. The method of claim 1, wherein said placing of said silicon material in said vacuum environment comprises holding said silicon material via a heating chuck.

8. A method of forming a silicide on a silicon material comprising:
placing said silicon material in vacuum environment, comprising holding said silicon material via a heating chuck;
forming metal on said silicon material without breaking said vacuum environment; and
heating said silicon material and said metal during said forming of said metal without breaking said vacuum environment.

9. The method in claim 8, further comprising performing additional heating of said silicon material.

10. The method in claim 9, wherein said heating forms a monosilicide and said additional heating forms a disilicide.

11. The method in claim 9, wherein said heating is performed at temperatures between 300° C. and 400° C. to form a metal rich silicide or between temperatures of 450° C. and 550° C. to form a monosilicide, and said additional heating is performed at temperatures above 600° C. to form a disilicide.

12. The method in claim 8, wherein said metal comprises one of Cobalt, Titanium, Platinum, and Nickel.

13. The method of claim 8, wherein said heating of said silicon material and of said metal comprises heating said silicon material and said metal such that said silicon material and said metal are heated on a heating chuck holding said silicon material.

14. A method of forming a silicide on a silicon material comprising:
placing said silicon material in vacuum environment, comprising holding said silicon material via a heating chuck;
forming metal on said silicon material without breaking said vacuum environment; and
heating said silicon material and said metal to a temperature greater than 300° C. during said forming of said metal without breaking said vacuum environment.

15. The method in claim 14, further comprising performing additional heating of said silicon material.

16. The method in claim 15, wherein said heating forms a monosilicide and said additional heating forms a disilicide.

17. The method in claim 15, wherein said heating is performed at temperatures between 300° C. and 400° C. to form a metal rich silicide or between temperatures of 450° C. and 550° C. to form a monosilicide, and said additional heating is performed at temperatures above 600° C. to form a disilicide.

18. The method in claim 14, wherein said metal comprises one of Cobalt, Titanium, Platinum, and Nickel.

19. The method of claim 14, wherein said heating of said silicon material and of said metal comprises heating said silicon material and said metal such that said silicon material and said metal are heated on a heating chuck holding said silicon material.
